(19) United States
(12) Patent Application Publication
(10) Pub. No.: US 2012/0275226 A1
(43) Pub. Date: Nov. 1, 2012

(54) NONVOLATILE SEMICONDUCTOR MEMORY DEVICE CAPABLE OF REDUCING POWER CONSUMPTION

(76) Inventors: Dai Nakamura, Fujisawa-shi (JP); Takatoshi Minamoto, Yokohama-shi (JP); Junji Musha, Yokohama-shi (JP); Mai Muramoro, Kamakura-shi (JP)

(21) Appl. No.: 13/428,384

(22) Filed: Mar. 23, 2012

(30) Foreign Application Priority Data
Apr. 28, 2011 (JP) 2011-100792

(51) Int. Cl. G11C 16/28; G11C 16/04; G11C 16/26

(52) U.S. Cl. 365/185.17; 365/185.2; 365/185.21

(57) ABSTRACT

According to one embodiment, a nonvolatile semiconductor memory device includes an electrically rewritable nonvolatile memory, a grounding pad, a first power supply pad, a second power supply pad, a voltage reduction circuit, and a first pump circuit. A first power supply is supplied to the first power supply pad. A second power supply, a voltage of which is higher than that of the first power supply is supplied to the second power supply pad. The voltage reduction circuit reduces the second power supply, generates a first voltage lower than that of the second power supply, and supplies the first voltage to the nonvolatile memory. The first pump circuit generates a voltage higher than that of the second power supply on the basis of the first power supply, and supplies the second voltage to the nonvolatile memory.

### CROSS-REFERENCE TO RELATED APPLICATIONS

This application is based upon and claims the benefit of priority from prior Japanese Patent Application No. 2011-100792, filed Apr. 28, 2011, the entire contents of which are incorporated herein by reference.

### FIELD

Embodiments described herein relate generally to an electrically rewritable nonvolatile semiconductor memory device such as a NAND flash memory or the like.

### BACKGROUND

A nonvolatile semiconductor memory device such as a NAND flash memory or the like requires various voltages in order to execute write, read, erase, and the like. The chip of the nonvolatile semiconductor memory device includes a VCC pad serving as a power supply pad, IO pad for input/output, VCCQ pad serving as a power supply pad dedicated to the output stage of a multi-bit output product, and VSS pad of the ground voltage. Therefore, various voltages necessary for write, read, erase, and the like are respectively boosted from a VCC power supply having a voltage of about 3 V by a booster circuit provided inside the chip. Accordingly, in order to generate necessary voltages, it is necessary to raise the voltage, thereby increasing the power consumption. Thus, reduction in the power consumption is desired.

### BRIEF DESCRIPTION OF THE DRAWINGS

FIG. 1 is a plan view schematically showing an example of a nonvolatile semiconductor memory device chip according to a first embodiment.

FIG. 2 is a block diagram showing examples of the VPP pad and voltage control circuit shown in FIG. 1.

FIG. 3 is a block diagram showing an example of the voltage control circuit according to the first embodiment.

FIG. 4 is a block diagram showing an example of a voltage control circuit according to a second embodiment.

FIG. 5 is a timing chart shown to explain an operation of the second embodiment.

FIG. 6 is a block diagram showing an example of a voltage control circuit according to a third embodiment.

FIG. 7 is a timing chart shown to explain an operation of the third embodiment.

### DETAILED DESCRIPTION

In general, according to one embodiment, a nonvolatile semiconductor memory device includes an electrically rewritable nonvolatile memory, a grounding pad, a first power supply pad, a second power supply pad, a voltage reduction circuit, and a first pump circuit. A ground voltage is supplied to the grounding pad. A first power supply is supplied to the first power supply pad. A second power supply, a voltage of which is higher than that of the first power supply is supplied to the second power supply pad. The voltage reduction circuit is connected to the second power supply pad. The voltage reduction circuit reduces the second power supply, generates a first voltage lower than the voltage of the second power supply, and supplies the first voltage to the nonvolatile memory. The first pump circuit generates a voltage higher than that of the second power supply on the basis of the first power supply, and supplies the second voltage to the nonvolatile memory.

For example, in a server or the like, a commercial power voltage (100 to 200 V) is used. When a nonvolatile semiconductor memory device is applied to this server, a DC voltage of 3.3 V is obtained from the commercial power voltage (100 to 200 V) by voltage reduction, and the DC voltage is supplied to the VCC pad of the nonvolatile semiconductor memory device. The nonvolatile semiconductor memory device produces necessary voltages by a voltage booster circuit in the chip.

Incidentally, in a power supply system of a server or the like, a system configured to output DC voltages such as 12 V, 5 V, 3.3 V, and the like from the commercial power voltage is employed as a system conforming to a unified standard. On the other hand, in the nonvolatile semiconductor memory device represented by a NAND flash memory, a voltage of about 30 V is produced from an external power supply of 3.3 V by an internal voltage booster circuit.

Thus, in this embodiment, it is attempted to reduce the power consumption of the chip by adding a VPP pad for 12 V to the chip in addition to the VCC pad for 3.3 V, and by using a voltage reduction circuit in place of the voltage booster circuit when a power supply voltage is supplied from the VPP pad.

Hereinafter, embodiments will be described with reference to the drawings.

### First Embodiment

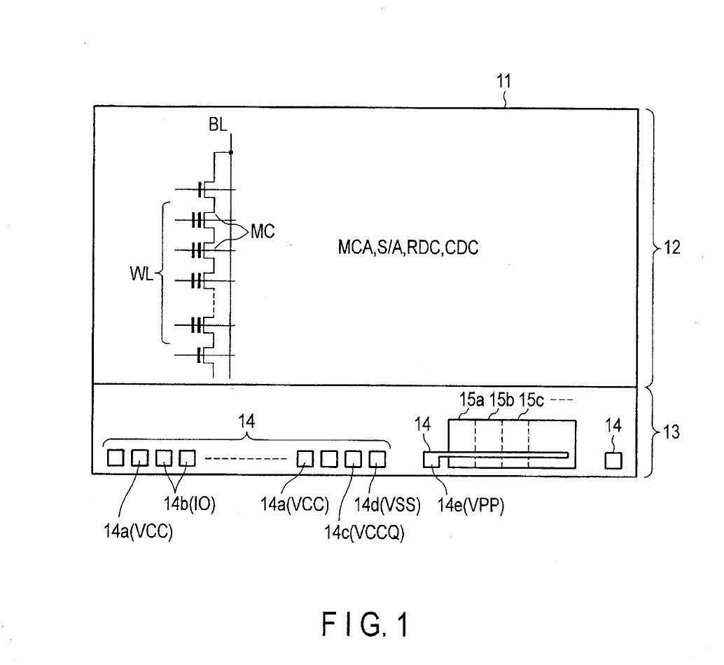

FIG. 1 schematically shows a chip of a nonvolatile semiconductor memory device, such as a NAND flash memory according to this embodiment.

In the chip 11, a memory cell array MCA, sense amplifier S/A, row decoder RDC, column decoder CDC, and the like which are not shown are arranged in a core circuit section 12. A plurality of memory cells MC constituting a NAND string are arranged in the memory cell array MCA. These memory cells MC are connected to word lines ML and a bit line BL. These memory cells MC are selected by the row decoder RDC, and column decoder CDC, and write of data to the memory cell, and read of data from the memory cell are executed through the sense amplifier S/A.

Further, a plurality of pads 14 are arranged in a peripheral circuit section 13 adjacent to the core circuit section 12. In these pads 14, for example, a VCC pad 14a serving as, for example, a power supply pad for 3.3 V, IO pad 14b for input/output, for example, VCCQ pad 14c for 3.3 V serving as a power supply pad dedicated to the output stage of a multi-bit output product, and VSS pad 14d for the ground voltage are included and, further a VPP pad 14e serving as, for example, a power supply pad for 12 V is also included. For example, a plurality of voltage control circuits 15a, 15b, 15c. . . are arranged to correspond to the VPP pad 14e.

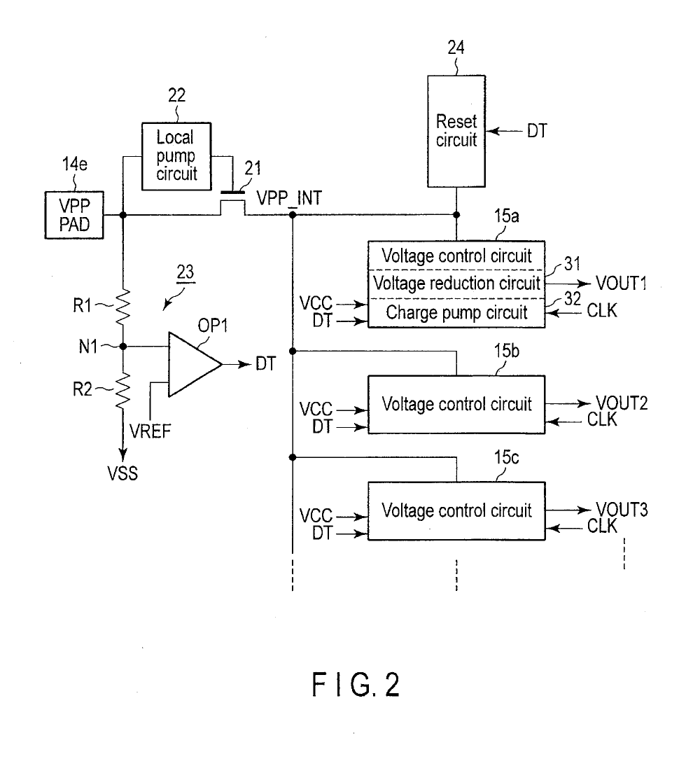

FIG. 2 shows the VPP pad 14e, and the plurality of voltage control circuits 15a, 15b, 15c . . . all of which are shown in FIG. 1.

One end of a current path of an N-channel MOS transistor (hereinafter referred to as an NMOS transistor) 21 is connected to the VPP pad 14e, and a local pump circuit 22 is also connected thereto. This local pump circuit 22 generates a voltage higher than a voltage 12V to be supplied to the VPP pad 14e by an amount corresponding to a threshold voltage Vth of the NMOS transistor 21. An output voltage VPP+Vth of the local pump circuit 22 is supplied to a gate electrode of the NMOS transistor 21. Accordingly, an internal voltage VPP_INT equal to the voltage VPP is output from the other end of the current path of the NMOS transistor 21. The NMOS transistor 21 functions as a switch configured to connect the VPP pad 14e, and voltage control circuits 15a, 15b, 15c . . . to each other.

Further, a detection circuit 23 is connected to the VPP pad 14e. This detection circuit 23 detects whether or not the power supply VPP is supplied to the VPP pad 14e. That is, the detection circuit 23 is constituted of resistors R1 and R2 connected in series between the VPP pad 14e and ground, and an operational amplifier OP1. One input end of the operational amplifier OP1 is connected to a connection node N1 between the resistors R1 and R2, and a reference voltage VREF is supplied to the other input end thereof. The operational amplifier OP1 outputs, when a voltage of the connection node N1 is lower than the reference voltage VREF, for example, a signal DT of a high level. This signal DT is supplied to the voltage control circuits 15a, 15b, 15c . . . , and a reset circuit 24.

Furthermore, the reset circuit 24 is connected to the other end of the current path of the NMOS transistor 21. When the power supply VPP is not supplied to the VPP pad 14e, the reset circuit 24 resets the other end of the current path of the NMOS transistor 21 to VCC or VSS. That is, when the power supply VPP is not supplied to the VPP pad 14e, the reset circuit 24 prevents the other end of the current path of the NMOS transistor 21 from entering a floating state.

Further, the plurality of voltage control circuits 15a, 15b, 15c . . . are connected to the other end of the current path of the NMOS transistor 21. These voltage control circuits 15a, 15b, 15c . . . output, when the power supply VPP is supplied to the VPP pad 14e, output voltages VOUT1, VOUT2, VOUT3 . . . , respectively by voltage reduction of the power supply VPP, and output, when the power supply VPP is not supplied to the VPP pad 14e, output voltages VOUT1, VOUT2, VOUT3 . . . , respectively by voltage boosting of the power supply VCC. For this reason, as will be described later, each of the voltage control circuits 15a, 15b, 15c . . . includes a voltage reduction circuit 31, and charge pump circuit 32.

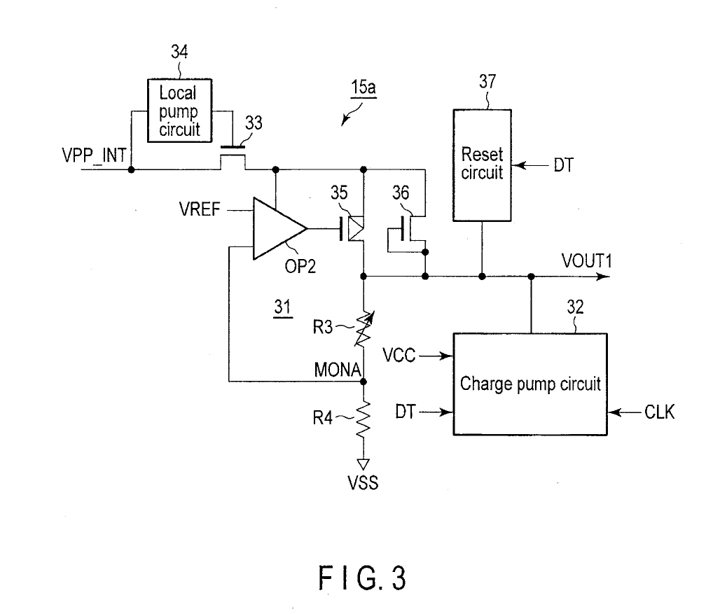

FIG. 3 shows the configuration of each of the voltage control circuits 15a, 15b, 15c . . . . The voltage control circuits 15a, 15b, 15c . . . each have the same configuration, and hence only the configuration of the voltage control circuit 15a will be described below.

In FIG. 3, the internal voltage VPP_INT is supplied to one end of a current path of an NMOS transistor 33 functioning as a switch, and an input end of a local pump circuit 34. The local pump circuit 34 generates a voltage VPP_INT+Vth higher than the internal voltage VPP_INT by an amount corresponding to the threshold voltage of the NMOS transistor 33 from the internal voltage VPP_INT. An output voltage of the local pump circuit 34 is supplied to a gate electrode of the NMOS transistor 33. Accordingly, the internal voltage VPP_INT is output from the other end of the current path of the NMOS transistor 33. This internal voltage VPP_INT is supplied to a voltage reduction circuit 31. It should be noted that it is also possible to use a level-shift circuit in place of the local pump circuit 34.

The voltage reduction circuit 31 is constituted of an operational amplifier OP2, P-channel MOS transistor (hereinafter referred to as a PMOS transistor) 35, and resistors R3 and R4. The PMOS transistor 35, and resistors R3 and R4 are connected in series between the other end of the current path of the NMOS transistor 33, and ground. A reference voltage VREF is supplied to one input end of the operational amplifier OP2, and the other input end thereof is connected to a connection node MONA between the resistors R3 and R4. An output end of the operational amplifier OP2 is connected to a gate electrode of the PMOS transistor 35.

A connection node between the PMOS transistor 35 and resistor R3 is an output node, and an output voltage VOUT1 is output from this output node.

A diode-connected NMOS transistor 36 is connected between one end and the other end of a current path of the PMOS transistor 35. This NMOS transistor 36 produces a power supply of the voltage reduction circuit 31. The NMOS transistor 36 charges a connection node between the PMOS transistor 35 and the resistance R3 at voltage VOUT1−Vth, and protects the PMOS transistor 35, when the internal voltage VPP_INT is not supplied.

Furthermore, a charge pump circuit 32, and reset circuit 37 are connected to the output node. The reset circuit 37 is identical to the reset circuit 24 shown in FIG. 2. Further, the charge pump circuit 32 is constituted of, for example, a plurality of capacitors, and a plurality of diode-connected transistors, and boosts up the power supply VCC on the basis of a clock signal CLK. An operation of the charge pump circuit 32 is controlled on the basis of the output signal DT of the detection circuit 23. It should be noted that the clock signal CLK is used in common for the voltage control circuits 15a, 15b, 15c . . . .

In the above-mentioned configuration, when the nonvolatile semiconductor memory device is applied to, for example, an apparatus such as a server or the like capable of supplying a voltage of 12 V, a power supply VPP is supplied to the VPP pad 14e. In this case, on the basis of the output signal DT of the detection circuit 23, the charge pump circuit 32 is brought into a stopped state. Accordingly, the voltage control circuit 15a reduces the voltage VPP by using the voltage reduction circuit 31, and outputs the output voltage VOUT1 from the output node.

The output voltage VOUT1 is made variable according to the resistance value of the resistor R3. Accordingly, for example, a variable voltage of 3 V to 10 V or a fixed voltage of 7 V or 8 V is output as the output voltage VOUT1. The voltage of 3 V to 10 V is supplied to unselected word lines at the time of, for example, data write, and the voltage of 7 V or 8 V is used as a voltage configured to drive a switch of each circuit.

On the other hand, when the power supply VPP is not supplied to the VPP pad 14e, the charge pump circuit 32 is brought into a drivable state on the basis of the output signal DT of the detection circuit 23. Accordingly, the charge pump circuit 32 generates the output voltage VOUT1 according to the clock signal CLK on the basis of the power supply VCC.

According to the above-mentioned first embodiment, the VPP pad 14e capable of supplying, for example, the power supply VPP having a voltage of 12 V higher than the power supply VCC is provided in the chip 11 of the nonvolatile semiconductor memory device in addition to the VCC pad 14a to which the power supply voltage VCC is supplied and, when the power supply VPP is supplied to the VPP pad 14e, the required output voltage VOUT1 is generated by using the voltage reduction circuit 31 without using the charge pump circuit 32 of the voltage control circuit 15a. Accordingly, it is possible to improve the conversion efficiency of electric power, and reduce the power consumption as compared with the case where the required output voltage VOUT1 is generated from the power supply VCC by using the charge pump circuit 32.

That is, when the charge pump circuit 32 is used, the power supply VCC (3.3 V) is generated from the commercial power of 100 V to 200 V, and the power supply VCC is boosted, and hence the conversion efficiency of the power lowers, and the power consumption increases as compared with the case where the power supply VPP (12 V) is generated from the commercial power (100 V to 200 V), and the power supply VPP is reduced. However, when the power supply VPP is supplied, the charge pump circuit 32 is stopped, and hence the power consumption can be reduced.

### Second Embodiment

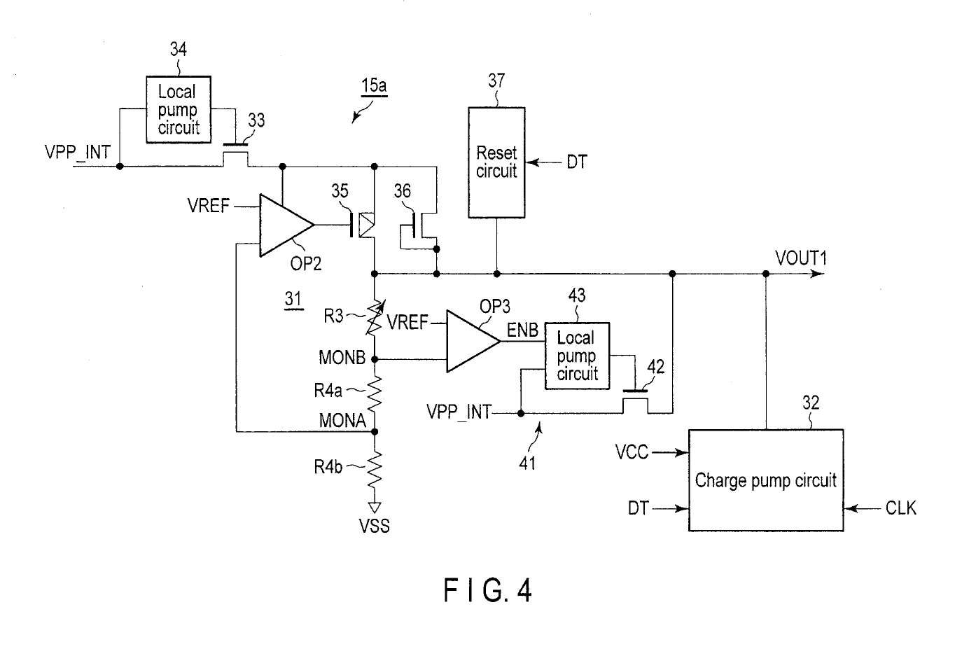

FIG. 4 shows a second embodiment. In FIG. 4, parts identical to those of FIG. 3 are denoted by identical reference symbols, and only parts different from those of FIG. 3 will be described below.

In the first embodiment described above, the case where a load of, for example, word lines connected to a voltage reduction circuit 31 largely varies is considered. In the voltage reduction circuit 31 using an operational amplifier OP2, the current supply capability of a PMOS transistor 35 constituting the output stage is determined by the gate width W. Accordingly, when the load of the word lines is small, no problem occurs even if the gate width W is small. However, when most of word lines of the same block are connected as the load as in the case of, for example, a read operation of the NAND flash memory, if the gate width W of the PMOS transistor 35 is small, the capability for charging the word lines lowers. Accordingly, it is necessary to make the gate width W of the PMOS transistor 35 larger.

However, when the gate width W of the PMOS transistor 35 is made larger, there is a problem that the operational amplifier OP2 is liable to oscillate when the load of the word lines is small.

Thus, as shown in FIG. 4, in the second embodiment, a supply circuit 41 configured to supply the internal voltage VPP_INT is provided at the output node of the voltage reduction circuit 31.

The supply circuit 41 is constituted of, for example, an operational amplifier OP3, NMOS transistor 42 functioning as a switch, and local pump circuit 43.

A reference voltage VREF is supplied to one input end of the operational amplifier OP3, and the other input end thereof is connected to a connection node MONB between a resistor R3 and resistor R4a both of which constitute a voltage reduction circuit 31. Here, the other input end of an operational amplifier OP2 constituting the voltage reduction circuit 31 is connected to a connection node MONA between a resistor R4a and resistor R4b.

An output end of the operational amplifier OP3 is connected to the local pump circuit 43. The internal voltage VPP_INT is supplied to an input end of the local pump circuit 43, and one end of a current path of the NMOS transistor 42. The local pump circuit 43 generates a voltage VPP_INT+Vth higher than the internal voltage VPP_INT by an amount corresponding to the threshold voltage of the NMOS transistor 42 from the internal voltage VPP_INT. An output voltage of the local pump circuit 43 is supplied to a gate electrode of the NMOS transistor 42. Accordingly, a voltage equal to the voltage VPP_INT can be output from the other end of the current path of the NMOS transistor 42. The other end of the current path of the NMOS transistor 42 is connected to the output node of the voltage reduction circuit 31. It should be noted that it is also possible to use a level-shift circuit in place of the local pump circuit 43.

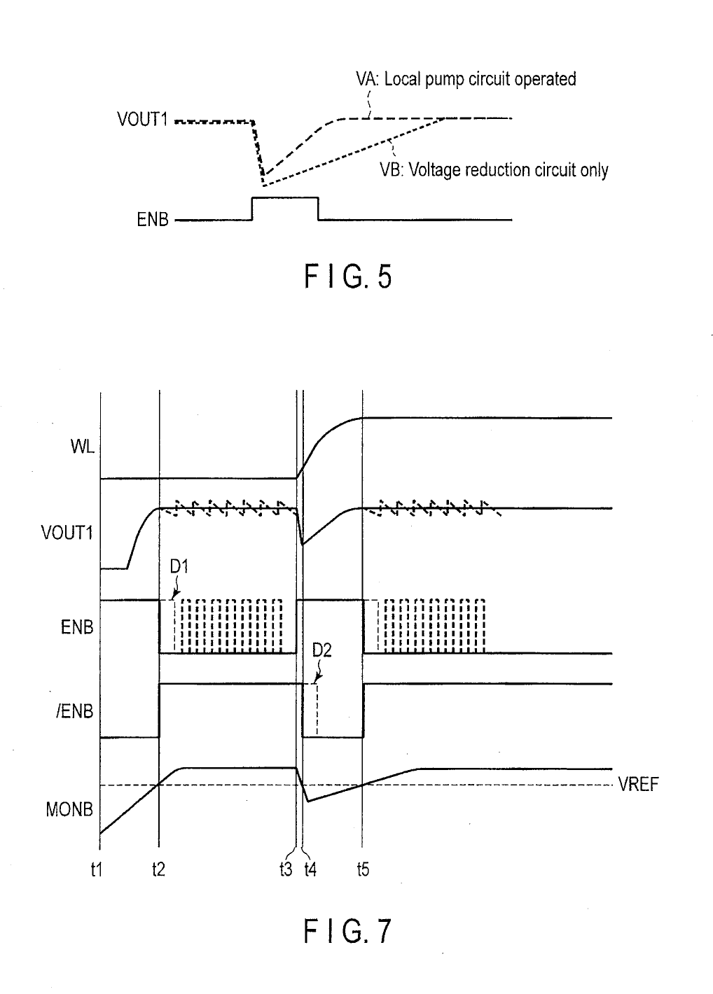

In the above-mentioned configuration, an operation of the second embodiment will be described below with reference to FIG. 5.

The voltage reduction circuit 31 detects the potential of the connection node MONA between the resistor R4a and resistor R4b to thereby control the PMOS transistor 35. In this state, when the load of the word lines connected to the output node of the voltage reduction circuit 31 increases, and the output voltage VOUT1 of the voltage reduction circuit 31 lowers, the potential of the connection node MONA between the resistor R4a and resistor R4b, and the potential of the connection node MONB between the resistor R3 and resistor R4a also lower.

The operational amplifier OP3 compares the voltage of the connection node MONB of the voltage reduction circuit 31 with the reference voltage VREF and, when the voltage of the connection node MONB becomes lower than the reference voltage VREF, the amplifier OP3 outputs, for example, a signal ENB of the high level. The local pump circuit 43 is activated in accordance with the signal ENB. Accordingly, the NMOS transistor 42 is turned on by the output voltage of the local pump circuit 43, and the internal voltage VPP_INT is supplied to the output node of the voltage reduction circuit 31 through the NMOS transistor 42.

That is, as shown by VA in FIG. 5, it is possible to boost up the output voltage VOUT1 of the voltage reduction circuit 31 concomitantly with the operation of the local pump circuit 43 more quickly than VB using no supply circuit 41. Accordingly, when the load of the word lines increases, it is possible to keep the output voltage VOUT1 quickly and stably by supplying the internal voltage VPP_INT to the output node of the voltage reduction circuit 31 from the supply circuit 41.

According to the above-mentioned second embodiment, the supply circuit 41 is provided at the output node of the voltage reduction circuit 31 and, when the current supply capability of the voltage reduction circuit 31 lowers, the voltage is supplied to the output node from the supply circuit 41. As a result, it is possible to keep the output voltage VOUT1 of the voltage reduction circuit 31 quickly and stably in response to the variations in load.

Further, when the load becomes stable, the supply circuit 41 is stopped, and the voltage of the load is held by the voltage reduction circuit 31. This makes it possible to reduce the power consumption.

Furthermore, by providing the supply circuit 41 at the output node of the voltage reduction circuit 31, it is not necessary to make the gate width W of the PMOS transistor 35 constituting the output stage of the voltage reduction circuit 31 large. As a result, it is possible to prevent the operational amplifier OP2 from oscillating.

### Third Embodiment

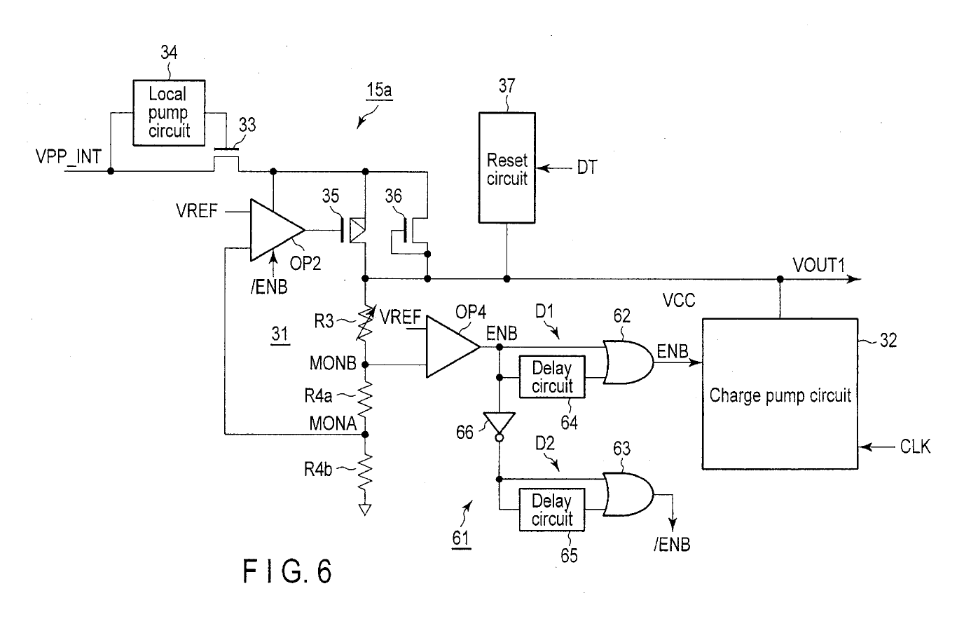

FIG. 6 shows a third embodiment. In FIG. 6, parts identical to those of FIG. 4 are denoted by identical reference symbols, and only parts different from those of FIG. 4 will be described below.

In the write operation or the read operation of the NAND flash memory, levels of voltages to be supplied to selected word lines, and unselected word lines are made different from each other. When different voltages are supplied to the word lines as described above, it is desirable from the viewpoint of improving the reliability that rising waveforms of voltages to be supplied to the word lines be equal to each other in shape because it becomes hard for the channels of cells in the NAND string to be locally boosted.

In the second embodiment, when the load increases, it is made possible to quickly charge the word lines by assisting the output voltage VOUT1 by means of the supply circuit 41. However, it is difficult to make the rising waveforms of the output voltages VOUT1, VOUT2, VOUT3 . . . equal to each other in shape in response to various variations in load by using the plurality of voltage control circuits 15a, 15b, 15c . . . as shown in FIG. 2.

That is, when the power supply VPP is supplied to the VPP pad 14e, the voltage control circuits 15a, 15b, 15c . . . output, at the time of startup, the output voltages VOUT1, VOUT2, VOUT3 . . . by using the voltage reduction circuits 31. However, it is difficult to make the rising waveforms of the output voltages VOUT1, VOUT2, VOUT3 . . . equal to each other in shape by using the voltage reduction circuits 31. When output voltage waveforms of a plurality of voltage reduction circuits are to be made equal to each other in shape, it becomes necessary to use a complicated control circuit, and there is the possibility of the chip size being increased.

Conversely, a charge pump circuit 32 is driven according to a clock signal CLK and, by changing the frequency of the clock signal CLK in accordance with the load, it is possible to change the voltage supply capability.

Thus, in the third embodiment, when charging of the word lines as the load is started, the voltage reduction circuit 31 is stopped, and a charge pump circuit 32 is operated and, when the voltage of the word lines enters the steady state, the charge pump circuit 32 is stopped, and the voltage reduction circuit 31 is operated, whereby it is made possible to make the rising waveforms of the plurality of voltages equal to each other in shape by using a circuit of a simple configuration.

As shown in FIG. 6, in the third embodiment, a timing control circuit 61 is provided between the voltage reduction circuit 31 and charge pump circuit 32.

The timing control circuit 61 is constituted of, for example, an operational amplifier OP4, OR circuits 62 and 63, delay circuits 64 and 65, and inverter circuit 66.

A reference voltage VREF is supplied to one input end of the operational amplifier OP4, and the other input end thereof is connected to a connection node MONB between a resistor R3 and resistor R4a both of which constitute the voltage reduction circuit 31. An output end of the operational amplifier OP4 is connected to one input end of the OR circuit 62, and is further connected to the other input end of the OR circuit 62 through the delay circuit 64. An output end of the OR circuit 62 is connected to the charge pump circuit 32.

Further, the output end of the operational amplifier OP4 is connected to one input end of the OR circuit 63 through the inverter circuit 66, and is further connected to the other input end of the OR circuit 63 through the delay circuit 65. An output end of the OR circuit 63 is connected to a power supply end of the operational amplifier OP2 constituting the voltage reduction circuit 31.

The above-mentioned OR circuits 62 and 63, and delay circuits 64 and 65 each constitute falling-edge delay circuits D1 and D2 configured to delay falling edges of a signal ENB output from the operational amplifier OP4, and signal /ENB, respectively by a predetermined time.

In the above-mentioned configuration, an operation of the third embodiment will be described below with reference to FIG. 7.

First, at time t1, when the word lines are connected to the output node of the voltage control circuit 15a as the load, the voltage reduction circuit 31 is stopped, and the charge pump circuit 32 is activated to charge the word lines and, when the voltage of the word lines gets close to the required voltage (target voltage) by the operation of the operational amplifier OP4, the charge pump circuit 32 is stopped, and the voltage reduction circuit 31 is activated to thereby supply a stable voltage to the word lines from the voltage reduction circuit 31.

That is, at time tl shown in FIG. 7, for example, when a write operation or a read operation is started, the voltage of the output node of the voltage reduction circuit 31 is in a state where the voltage is lower than the reference voltage VREF. Accordingly, the output signal ENB of the operational amplifier OP4 constituting the timing control circuit 61 is at the high level, and the signal ENB is supplied to the charge pump circuit 32 through the falling-edge delay circuit D1.

The charge pump circuit 32 is activated on the basis of the signal ENB, and starts the voltage boosting operation. Accordingly, the output voltage VOUT1 of the voltage control circuit 15a rises. At this time, the word lines WL are not connected to the output node of the voltage control circuit 15a yet, and hence the potential of the word lines WL does not change.

Furthermore, at this time, the output signal /ENB of the operational amplifier OP4 inverted by the inverter circuit 66 is supplied to the operational amplifier OP2 constituting the voltage reduction circuit 31 through the falling-edge delay circuit D2 constituted of the delay circuit 65. Accordingly, the operational amplifier OP2 is set to the stopped state on the basis of the output signal /ENB.

Concomitantly with the operation of the charge pump circuit 32, the output voltage VOUT1 rises and, when the voltage of the connection node MONB of the voltage reduction circuit 31 becomes higher than or equal to the reference voltage VREF (time t2), the output signal ENB of the operational amplifier OP4 is inverted to the low level. The signal ENB is delayed by the falling-edge delay circuit D1, and then is supplied to the charge pump circuit 32 as indicated by a broken line in FIG. 7. Accordingly, the charge pump circuit 32 is stopped.

On the other hand, the signal /ENB output from the operational amplifier OP4, and inverted by the inverter circuit 66 is supplied to the operational amplifier OP2 constituting the voltage reduction circuit 31 through the falling-edge delay circuit D2. At this time, the rising edge of the signal /ENB is not delayed, and hence the operational amplifier OP2 is activated before the charge pump circuit 32 is stopped. Accordingly, the output voltage VOUT1 is output without interruption. In this state, the output voltage VOUT1 is held by the voltage reduction circuit 31.

After this, at time t3, when the word lines WL are connected to the output node of the voltage control circuit 15a, the voltage of the connection node MONB of the voltage reduction circuit 31 becomes somewhat lower than the reference voltage VREF at time t4. Accordingly, the output signal ENB of the operational amplifier OP4 changes from the low level to the high level. The signal ENB is supplied to the charge pump circuit 32 through the falling-edge delay circuit D1 without being delayed. Accordingly, the charge pump circuit 32 immediately starts the boosting operation in response to the signal ENB.

Further, the signal /ENB inverted by the inverter circuit 66 is delayed by the falling-edge delay circuit D2, and is thereafter supplied to the voltage reduction circuit 31. Accordingly, the voltage reduction circuit 31 is stopped after the charge pump circuit 32 is activated, and hence it is possible to prevent the output voltage VOUT1 from largely lowering.

After this, the output voltage VOUT1 rises, and when the voltage of the connection node MONB exceeds the reference voltage VREF at time t5, the charge pump circuit 32 is stopped by the above-mentioned operation, and the voltage reduction circuit 31 is driven. After this, the voltage of the word lines WL is held by the voltage reduction circuit 31.

According to the above-mentioned third embodiment, when charging of the word lines is started, the voltage reduction circuit 31 is stopped, the word lines are charged by the charge pump circuit 32 and, when the voltage of the word lines gets close to the target voltage, the charge pump circuit 32 is stopped, and a stable voltage is supplied to the word lines by the voltage reduction circuit 31. The charge pump circuit 32 constituting each of the voltage control circuits 15a, 15b, 15c . . . is operated by the same clock signal (not shown). Accordingly, it is possible to simultaneously activate all the charge pump circuits 32 each constituting each of the voltage control circuits 15a, 15b, 15c . . . , and make the rising edges of the output voltages VOUT1, VOUT2, VOUT3 of the voltage control circuits 15a, 15b, 15c . . . equal to each other in shape.

Further, the configuration necessary to carry out the above-mentioned control is essentially constituted of the operational amplifier OP4 and inverter circuit 66, and hence it is possible to realize the above control by a simple configuration.

Furthermore, the charge pump circuit 32 operates when charging of the word lines is started and, if the word lines reach the target voltage, the voltage of the word lines is held by the voltage reduction circuit 31, and the charge pump circuit 32 is in the stopped state, whereby it is possible to reduce the power consumption.

Further, the falling edge of the output signal ENB of the operational amplifier OP4 is delayed by the falling-edge delay circuit D1 or D2. Accordingly, it is possible to make the operations of the charge pump circuit 32, and voltage reduction circuit 31 overlap with each other. Accordingly, when the operation mode is switched to/from the charge pump circuit 32 from/to the voltage reduction circuit 31, it is possible to prevent the output voltage VOUT1 of the voltage control circuit 15a from lowering.

Furthermore, in the state where the output voltage VOUT1 of the voltage control circuit 15a reaches the target voltage, the charge pump circuit 32 is stopped, and the voltage reduction circuit 31 is driven. Assuming that the above-mentioned operation is carried out by using only the charge pump circuit 32 without using the voltage reduction circuit 31, even after the output voltage VOUT1 reaches the target voltage, the charge pump circuit 32 operates. In this case, it is conceivable that each time the voltage of the connection node MONB becomes lower than the reference voltage VREF as indicated by broken lines in FIG. 7, the signal ENB of the high level will be output from the operational amplifier OP4, and the charge pump circuit 32 will be frequently driven. Accordingly, it is further conceivable that the output voltage VOUT1 will exhibit a saw-toothed waveform as indicated by broken lines in FIG. 7, and the output voltage VOUT1 will become unstable.

However, as in the third embodiment, after the output voltage VOUT1 reaches the target voltage, it is possible to stably hold the output voltage VOUT1 by supplying the output voltage VOUT1 by means of the voltage reduction circuit 31.

It should be noted that it is possible to omit the detection circuit 23 shown in FIG. 2 when it is not necessary to detect the voltage of the VPP pad 14e.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
an electrically rewritable nonvolatile memory;
a grounding pad to which a ground voltage is supplied;
a first power supply pad to which a first power supply is supplied;
a second power supply pad to which a second power supply a voltage of which is higher than a voltage of the first power supply is supplied;
a voltage reduction circuit connected to the second power supply pad, the voltage reduction circuit configured to reduce the second power supply, to generate a first voltage lower than the voltage of the second power supply, and to supply the first voltage to the nonvolatile memory; and
a first pump circuit configured to generate a second voltage higher than the voltage of the second power supply on the basis of the first power supply, and to supply the second voltage to the nonvolatile memory.

2. The device according to claim 1, further comprising a first detection circuit configured to compare a first voltage generated by the voltage reduction circuit and a reference voltage with each other and, output a signal used to activate the first pump circuit when the first voltage is lower than the reference voltage.

3. The device according to claim 2, further comprising a delay circuit configured to delay the output signal of the first detection circuit.

4. The device according to claim 1, further comprising
a second detection circuit configured to compare the voltage generated by the voltage reduction circuit and a reference voltage with each other, and output a signal; and
a supply circuit configured to supply the second power supply to an output end of the voltage reduction circuit on the basis of the output signal of the second detection circuit.

5. The device according to claim 4, wherein
the supply circuit comprises
a transistor to which the second power supply is supplied; and
a second pump circuit configured to generate a voltage to be supplied to a gate electrode of the transistor.

6. The device according to claim 1, further comprising a third detection circuit connected to the second power supply pad, wherein
the third detection circuit detects whether or not the second power supply is supplied to the second power supply pad, stops the first pump circuit and operates the voltage reduction circuit when the second power supply is supplied to the second power supply pad, and operates the first pump circuit and stops the voltage reduction circuit when the second power supply is not supplied to the second power supply pad.

7. The device according to claim 1, wherein
the nonvolatile memory has a plurality of NAND strings constituted by a plurality of memory cells.

8. A nonvolatile semiconductor memory device comprising:
a memory core; and
a peripheral circuit, wherein
the peripheral circuit comprises
a grounding pad to which a ground voltage is supplied;
a first power supply pad to which a first power supply is supplied;
a second power supply pad to which a second power supply a voltage of which is higher than a voltage of the first power supply is supplied;
a voltage reduction circuit connected to the second power supply pad, and configured to reduce the second power supply, to generate a first voltage lower than the voltage of the second power supply, and to supply the first voltage to the memory core; and
a first pump circuit configured to generate a second voltage higher than the voltage of the second power supply on the basis of the first power supply, and to supply the second voltage to the memory core.

9. The device according to claim 8, further comprising a first detection circuit configured to compare a first voltage generated by the voltage reduction circuit and a reference voltage with each other and, output a signal used to activate the first pump circuit when the first voltage is lower than the reference voltage.

10. The device according to claim 9, further comprising a delay circuit configured to delay the output signal of the first detection circuit.

11. The device according to claim 8, further comprising
a second detection circuit configured to compare the voltage generated by the voltage reduction circuit and a reference voltage with each other, and output a signal; and
a supply circuit configured to supply the second power supply to an output end of the voltage reduction circuit on the basis of the output signal of the second detection circuit.

12. The device according to claim 11, wherein
the supply circuit comprises
a transistor to which the second power supply is supplied; and
a second pump circuit configured to generate a voltage to be supplied to a gate electrode of the transistor.

13. The device according to claim 8, further comprising a third detection circuit connected to the second power supply pad, wherein
the third detection circuit detects whether or not the second power supply is supplied to the second power supply pad, stops the first pump circuit and operates the voltage reduction circuit when the second power supply is supplied to the second power supply pad, and operates the first pump circuit and stops the voltage reduction circuit when the second power supply is not supplied to the second power supply pad.

14. The device according to claim 8, wherein
the memory core has a plurality of NAND strings constituted by a plurality of memory cells.
